(19) United States
(12) Patent Application Publication
(10) Pub. No.: US 2018/0123616 A1
(43) Pub. Date: May 3, 2018

(54) DECODING METHOD FOR CONVOLUTIONAL CODE DECODING DEVICE IN COMMUNICATION SYSTEM AND ASSOCIATED DETERMINATION MODULE

(71) Applicant: MStar Semiconductor, Inc., Hsinchu Hsien (TW)

(72) Inventor: Yu-Hsien KU, Hsinchu Hsien (TW)

(21) Appl. No.: 15/786,918

(22) Filed: Oct. 18, 2017

(30) Foreign Application Priority Data
Oct. 28, 2016 (TW) 105134927

(51) Int. Cl. H03M 13/39; H03M 13/27; H03M 13/37; H04L 1/00

(52) U.S. Cl. CPC H03M 13/3905; H03M 13/27; H04L 1/005; H04L 1/0071; H03M 13/3746

(57) ABSTRACT

A decoding method for a convolutional code decoding device in a communication system includes receiving convolutional code data, determining the number of times of iteration, and performing an iterative decoding process for the number of times of iteration to decode the convolutional code data.

This application claims the benefit of Taiwan application Serial No. 105134927, filed Oct. 28, 2016, the subject matter of which is incorporated herein by reference.

### BACKGROUND OF THE INVENTION

### Field of the Invention

The invention relates in general to a decoding method for a convolutional code decoding device in a communication system and an associated determination module, and more particularly to decoding method capable of adjusting the number of times of iteration of a convolutional code decoding process according to a symbol rate of convolutional code data received, and an associated determination module.

### Description of the Related Art

When a wireless signal is transmitted in a wireless channel of a wireless communication system, the wireless signal may encounter frequency and time selective fading while passing the wireless channel and become attenuated, which eventually leads to signal distortion. To alleviate the effects of the wireless channel, a transmitter in the wireless communication system may first perform processes including encoding, modulation and interleaving on data to be transmitted, and transmit the data wirelessly. As such, when a receiver in the wireless communication system receives the wireless signal, the receiver may perform processes including channel estimation, demodulation and error correction (ECC) decoding to restore the impaired reception signal.

A prototypic receiver includes a channel estimator and an error correction decoder. The channel estimator estimates a channel response to recover distortion of the phase and amplitude of the reception signal. The error correction decoder corrects bits with decision errors in the reception signal according to an error correction code. Common error correction codes include the convolutional code, low density parity check code (LDPC) and turbo code. As the turbo code is proven to approximate the Shannon limit of the transmission theory, the turbo code has been extensively applied in satellite communication, digital image transmission, and Third Generation Partnership Project (3GPP) Long-Term Evolution (LTE).

Multiple times of iteration calculation is needed in the decoding process of the turbo code to achieve outstanding accuracy. However, the numerous times of iterative operation significantly delays the speed of decoding. Therefore, there is a need for a solution that simultaneously attends to the decoding speed and the decoding accuracy.

### SUMMARY OF THE INVENTION

The invention is directed to a decoding method capable of adjusting the number of times of iteration of a convolutional code decoding process according to a symbol rate of convolutional code data received, and an associated determination module.

The present invention discloses a decoding method for a convolutional code decoding device in a communication system. The decoding method includes receiving convolutional code data, determining the number of times of iteration according to a symbol rate of the convolutional code data, and performing an iterative decoding process for the number of times of iteration to decode the convolutional code data.

The present invention further discloses a determination module for a convolutional code decoding device in a communication system. The determination module includes: an arithmetic circuit, calculating a difference between a symbol rate of convolutional code data that the convolutional code decoding device receives and a symbol rate threshold as a difference signal; a determination circuit, generating a selection signal according to the difference signal; and a selection circuit, outputting one of a first length and a second length according to the selection signal as a sliding window length of an iterative decoding process that the convolutional code decoding device performs.

The above and other aspects of the invention will become better understood with regard to the following detailed description of the preferred but non-limiting embodiments. The following description is made with reference to the accompanying drawings.

### BRIEF DESCRIPTION OF THE DRAWINGS

FIG. 1 is a block diagram of a decoding device according to an embodiment of the present invention;

FIG. 2 is a schematic diagram of associated signals in an operation of the decoding device in FIG. 1;

FIG. 3 is a schematic diagram of associated signals in an operation of the decoding device in FIG. 1;

FIG. 4 is a schematic diagram of associated signals in an operation of the decoding device in FIG. 1;

FIG. 5 is a flowchart of a decoding method according to an embodiment of the present invention; and

FIG. 6 is a block diagram of a determination module according to an embodiment of the present invention.

### DETAILED DESCRIPTION OF THE INVENTION

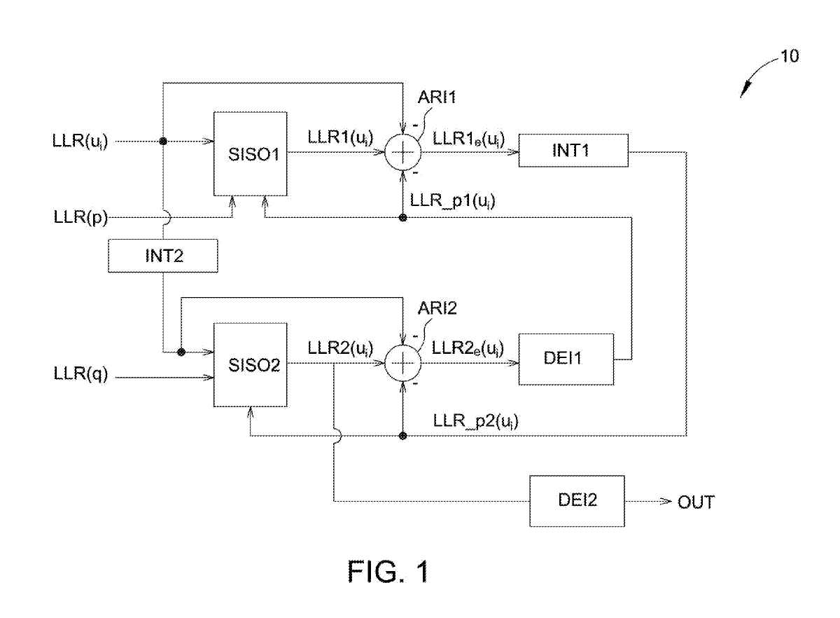

FIG. 1 shows a block diagram of a decoding device 10 according to an embodiment of the present invention. The decoding device 10 is applied to a turbo code decoder of a communication system to determine output information OUT of a data bit uᵢ. In this embodiment, the communication system is an electronic product with a communication function, for example but not limited to, a smart phone, a tablet computer, a laptop computer, and a wireless base station. As shown in FIG. 1, the decoding device 10 includes soft-in soft-out (SISO) decoding modules SISO1 and SISO2, arithmetic modules ARI1 and ARI2, interleavers INT1 and INT2, and de-interleavers DEI1 and DEI2. The decoding device 10 includes three sets of input information LLR(uᵢ), LLR(p) and LLR(q), where p and q are check bits of the data bit uᵢ, and LLR(uᵢ), LLR(p) and LLR(q) are respectively log-likelihood ratios (LLRs) of the data bit uᵢ and the check bits p and q. The SISO decoding module SISO1 generates extrinsic information LLR1(uᵢ) according to the input information LLR(uᵢ) and LLR(p) and a priori information LLR_p1(uᵢ). The arithmetic module ARI1 subtracts the input information LLR1(uᵢ) and the a priori information LLR_p1(uᵢ) from the extrinsic information LLR1(uᵢ) to generate extrinsic information LLR1e(uᵢ) to the interleaver INT1, which then rearranges the extrinsic information LLR1e(uᵢ) to generate a priori information LLR_p2(uᵢ) outputted to the SISO decoding module SISO2. Similarly, the SISO decoding module SISO2 generates extrinsic information LLR2e(uᵢ) according to the interleaved input information LLR(uᵢ), input information LLR(q) and a priori information LLR_p2(uᵢ) to the de-interleaver DEI1, which then rearranges the extrinsic information LLR2e(uᵢ) to generate a priori information LLR_p1(uᵢ) outputted to the SISO decoding module SISO1. By iterating the above iterative decoding process, the decoding device 10 generates reliable SISO output information OUT. Thus, the communication system may determine the value of the data bit uᵢ according to the output information OUT.

More specifically, when the decoder in the communication system receives a codeword that is convolutional coded data coded by turbo coding, the decoding device 10 is applied to decode the codeword to generate output information OUT of a plurality of data bits U₁ to Uₙ of the convolutional code data (i.e., sequentially inputting the data bits U₁ to Uₙ as the data bit uᵢ to the decoding device 10), and to accordingly determine the data bits U₁ to Uₙ. After the above iterative decoding process is performed, if the SISO decoding modules SISO1 and SISO2 adopt a maximum a posteriori probability (MAP) algorithm, the SISO decoding modules SISO1 and SISO2 need to individually calculate a forward state metric, a backward metric state and a branch metric state for different phases of receiving the convolutional code data, so as to further determine the MAP of each of the data bits U₁ to Uₙ. For example, when the decoding device 10 receives the convolutional code data, the SISO decoding modules SISO1 and SISO2 calculate the forward state metric, the backward state metric and the branch metric of phases L0 to Lj of the process of receiving the convolutional code data. In one embodiment, if the SISO decoding modules SISO1 and SISO2 are to calculate the forward state metric, the backward state metric and the branch metric of the phase Lk (0≤k≤j), the SISO decoding modules SISO1 and SISO2 calculate the forward state metric according to the convolutional code data that is received in the phases L0 to Lk, calculate the backward state metric according to the convolutional code data that is received in the phases Lj to Lk, and calculate the branch metric according to the convolutional code data that is received in the phase Lk+1 to Lk.

However, before the SISO decoding modules SISO1 and SISO2 calculate the backward state metric of the phases Lj to L0, the forward state metric and the branch metric of the phases L0 to Lj need to be first obtained. Thus, before the backward state metric of the phases Lj to L0 can be calculated and hence the MAP can be determined, the SISO decoding modules SISO1 and SISO2 need to finish receiving the convolutional code data at the phase Lj and calculate the forward state metric and the branch metric of the phases L0 to Lj. In this case, not only the SISO decoding modules SISO1 and SISO2 need to use a large amount of memory to store the forward state metric and the branch metric of the phases L0 to Lj, but the decoding device 10 also needs an excessively long decoding time.

To reduce the memory capacity needed and to increase the decoding speed, the SISO decoding modules SISO1 and SISO2 may adopt a sliding window architecture to reduce the data size needed for calculating the forward state metric, the backward state metric and the branch metric of each of the phases. For example, when the decoding device 10 receives convolutional code data, the SISO decoding modules SISO1 and SISO2 may divide the convolutional code data according to the size of the sliding window to obtain the phases L0 to Lⱼ, and start calculating the forward state metric, the backward state metric and the branch metric needed as the phase L2 begins. More specifically, at the phase Lk (2≤k≤j), the SISO decoding modules SISO1 and SISO2 calculate the forward metric of the phase Lk−1 according to the convolutional code data that is received in the phases Lk−2 to Lk−1, and calculate the branch metric of the phase Lk−1 according to the convolutional code data that is received in the phases Lk to Lk−1. After the forward metric and the branch metric of the phase Lk−1 are obtained in the phase Lk+1, the SISO decoding modules SISO1 and SISO2 may calculate the backward state metric of the phase Lk−2 according to the forward state metric and the branch metric of the phase Lk−1. Next, the SISO decoding modules SISO1 and SISO2 may accordingly decode the convolutional code data that is received in the phases Lk−2 to Lk−1 after the backward state metric of the phase Lk−2 is obtained.

Further, to achieve the object of real-time decoding, the time that the decoding device 10 requires for performing the iterative decoding needs to be shorter than the time that the communication system requires for receiving the convolutional code data. Thus, the number of times of the iterative decoding performed by the decoding device 10 may be represented as an equation below:

number of times of iteration:

$$floor ( \frac{( \frac{clockcycle \times FEC}{SR} ) - tre\_len - DS \times \frac{C 1 \times turbo\_clk}{FEC}}{\frac{tre\_len}{siso\_num} + SDW + SDW + C 2} ) \qquad ( 1 )$$

In the above equation, floor(x) is a function that obtains a maximum integer smaller than or equal to x (e.g., when x=3.14., floor(x)=3), clockcycle is a clock cycle of hardware in the communication system, FEC is the number of the decoding device 10 in the communication system, SR is a symbol rate of an output signal of a frontend circuit (e.g., the symbol rate of the convolutional code data received by the decoding device), tre_len is the length of the convolutional code data (e.g., the trellis length), DS is the number of unit data size in the convolutional code data (e.g., the number of the unit in tuples of convolutional code data), turbo_clk is the clock cycle of the decoding device 10, siso_num is the number of hardware in the SISO decoding modules SISO1 and SISO2 that processes the convolutional code data in parallel, SDW is the length of the sliding window. It should be noted that, in equation (1), C1 and C2 are parameters determined according to hardware characteristics of the communications system, wherein C2 is associated with the processing speeds of the SISO decoding modules SISO1 and SISO2. That is to say, the parameters C1 and C2 change along with hardware characteristics of different communication systems. In one embodiment, the parameters C1 and C2 are 2.2 and 10, respectively.

In brief, the denominator in the value of the function floor( ) is the time that the communication system requires for receiving the convolutional code data, and the numerator in the value of the function floor( ) is the time that the decoding device 10 requires to complete one round of iterative decoding. Thus, the value obtained though the equation (1) represents the number of times of iteration of the convolutional code decoding process that the decoding device 10 is capable of completing during the time in which the communication system receives the convolutional code data. That is to say, if the decoding device 10 adopts equation (1) to calculate the number of times of iteration that the decoding device 10 performs during the decoding process, the object of real-time decoding can be achieved.

In an embodiment of the present invention, the number of times of iteration that the decoding device 10 performs during the decoding process changes with the symbol rate SR of the convolutional code data to enhance the performance (e.g., the throughput) of the decoding device 10. When the symbol rate SR of the convolutional code data increases, the decoding device 10 increases the number of times of iteration performed within the convolutional code decoding process to maintain the decoding accuracy of the decoding device 10. In contrast, when the symbol rate SR of the convolutional coded data drops, the decoding device 10 reduces the number of times of iteration performed within the convolutional code decoding process. Because of the lower symbol rate SR of the convolutional code data, the decoding accuracy of the decoding device 10 still achieves the requirement of the communication system although the number of times of iteration is decreased. In other words, the number of times of iteration that the decoding device 10 performs within the convolutional code decoding process and the symbol rate SR of the convolutional code data are directly proportional. Thus, while achieving real-time decoding, the decoding device 10 is capable of enhancing the decoding performance.

In one embodiment, the decoding device 10 achieves the object of changing the number of times of iteration within the convolutional code decoding process according to the symbol rate SR of the convolutional code data through adjusting the length SDW of the sliding window. When the symbol rate SR of the convolutional code is increased, the length SDW of the sliding window is reduced to increase the number of times of iteration performed within the convolutional code decoding process to maintain the decoding accuracy of the decoding device 10. On the other hand, when the symbol rate SR of the convolutional code data is reduced, the length SDW of the sliding window is increased to reduce the number of times of iteration performed within the convolutional code decoding process. At this point, due to the lower symbol rate SR of the convolutional code data, the decoding accuracy of the decoding device 10 stills satisfies the requirement of the communication system although the number of times of iteration is reduced. That is to say, according to an embodiment of the present invention, the length SDW of the sliding window is adjusted according to the symbol rate SR of the convolutional code data received to determine the number of times of iteration performed within the convolutional code decoding process. By adjusting the length SDW of the sliding window (e.g., determining the number of times of iteration performed within the convolutional code decoding process) according to the symbol rate SR of the convolutional code data, the decoding device 10 is capable of simultaneously achieving real-time decoding and enhanced performance.

In one embodiment, when the number of times of iteration obtained according to the symbol rate SR and equation (1) is greater than 16, the decoding device 10 sets the length of the sliding window to SDW1, otherwise the decoding device 10 sets the length of the sliding window to SDW2. In this embodiment, the length SDW1 is greater than the length SDW2. That is to say, when the number of times of iteration is greater than 16, the decoding device 10 increases the length of the sliding window to reduce the number of times of iteration; conversely, the decoding device 10 increases the length of the sliding window to increase the number of times of iteration.

In another embodiment, when the symbol rate SR is smaller than a threshold SR_TH, the decoding device 10 sets the length of the sliding window to SDW1, otherwise the decoding device 10 sets the length of the sliding window to SDW2. In other words, the decoding device 10 determines whether the length of the sliding window is to be set to SDW1 to SDW2 according to the relationship between the values of the symbol rate SR and the symbol rate threshold SR_TH.

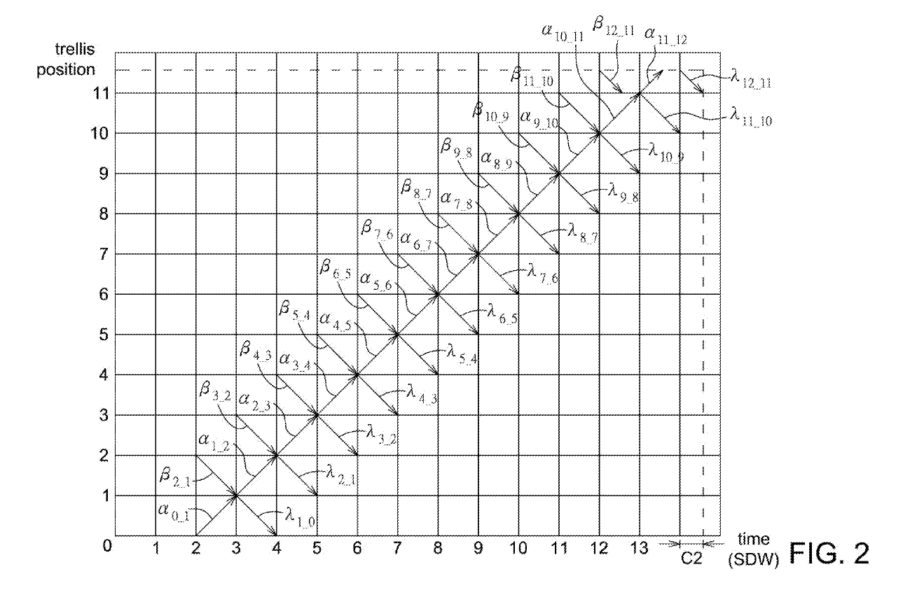

FIG. 2 shows a mapping diagram of trellis positions and time in an operation of the decoding device 10 in FIG. 1. The time is in a unit length of the length of the sliding window SDW. In FIG. 2, the length SDW of the sliding window is 48. As shown in FIG. 2, the decoding device 10 starts receiving data at a time point 0, and starts decoding at a time point 2*SDW. At a time point 2*SDW, the decoding device 10 calculates the branch metric β₂_{_}₁ of the convolutional code data between the time points 2*SDW and SDW, and the forward state metric a of the convolutional code data between the time points 0 and SDW. At a time point 3*SDW, the decoding device 10 calculates the branch metric β₃_{_}₂ of the convolutional code data between the time points 3*SDW and 2*SDW and the forward state metric α₁_{_}₂ of the convolutional code data between the time points SDW and 2*SDW, and calculates the backward state metric λ₁_{_}₀ of the convolutional code data between the time points SDW to 0 according to the branch metric α₀_{_}₁. After obtaining the backward state metric λ₁_{_}₀ of the time point SDW, the decoding device 10 decodes the convolutional code data between the time points 0 to SDW according to the forward state metric α₀_{_}₁ and the backward state metric λ₁_{_}₀. By repeating the above steps, after completely receiving the convolutional code data at the time point 12*SDW, the decoding device 10 may obtain the backward state metric λ₁₂_{_}₁₁ of the convolutional code data between the time points 12*SDW to 11*SDW at the time point 14*SDW+C2, and completes decoding the convolutional code data of the time point 11*SDW to 12*SDW. Known from FIG. 2, when the length of the sliding window is 48, the decoding device 10 needs a period of 14*48+C2 to completely decoding the convolutional code data.

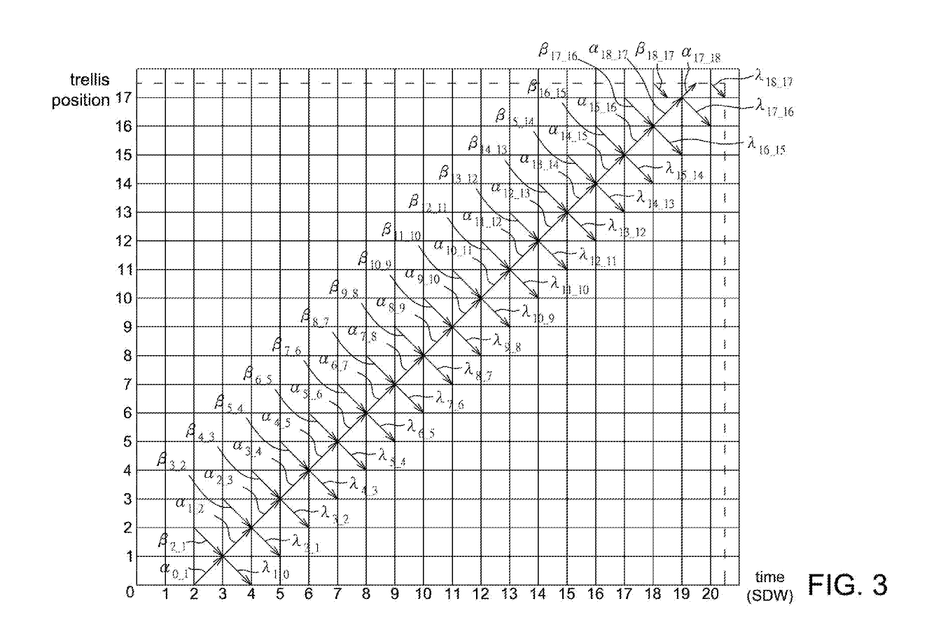

When the symbol rate of the convolutional code data is increased, the decoding device 10 reduces the length SDW of the sliding window to increase the number of times of iteration of the convolutional code decoding process. FIG. 3 shows a mapping diagram of trellis positions and time in an operation of the decoding device 10 in FIG. 1. The time is in a unit length of the length of the SDW of the sliding window, and the length SDW of the sliding window in FIG. 3 is reduced to 32. Details of the steps of the convolutional code decoding process performed by the decoding device 10 in FIG. 3 are similar to those performed by the decoding device 10 in FIG. 2, and shall be omitted for brevity. According to FIG. 3, when the length SDW of the sliding window is reduced from 48 to 32, and so the time that the decoding device 10 requires to decode convolutional code data having the same length is reduced to 32*20+C, thereby increasing the number of times of iteration of the convolutional code decoding process while achieving the decoding requirements. Therefore, when the symbol rate of the convolutional code data is increased, the decoding device 10 may reduce the length SDW of the sliding window to increase the number of times of iteration of the convolutional code decoding process to maintain the decoding accuracy of the decoding device 10.

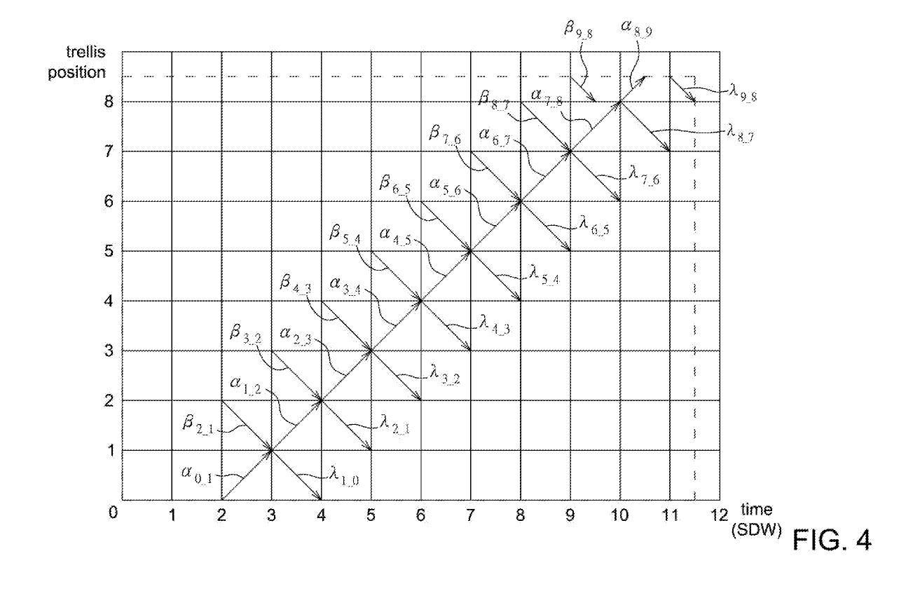

FIG. 4 shows a mapping diagram of trellis positions and time in an operation of the decoding device 10 in FIG. 1. The time is in a unit length of the length of the SDW of the sliding window, and the length SDW of the sliding window in FIG. 3 is increased to 64. Details of the steps of the convolutional code decoding process performed by the decoding device 10 in FIG. 4 are similar to those performed by the decoding device 10 in FIG. 2, and shall be omitted for brevity. Compared to FIG. 2, when the length SDW of the sliding window is increased from 48 to 64, the time that the decoding device 10 requires to decode convolutional code data having the same length is increased, thereby reducing the number of times of iteration of the convolutional code decoding process while achieving the decoding requirements. Due to the reduced symbol rate of the convolutional code data, the decoding accuracy of the decoding device 10 still achieves system requirements although the number of times of iteration of the convolutional code decoding process is reduced. Therefore, when the symbol rate of the convolutional code data is reduced, the decoding device 10 may increase the length SDW of the sliding window to reduce the number of times of iteration of the convolutional code decoding process. Because the symbol rate SR of the convolutional code data is lower, the decoding accuracy of the decoding device 10 still achieves the requirements of the communication system although the number of times of iteration is reduced.

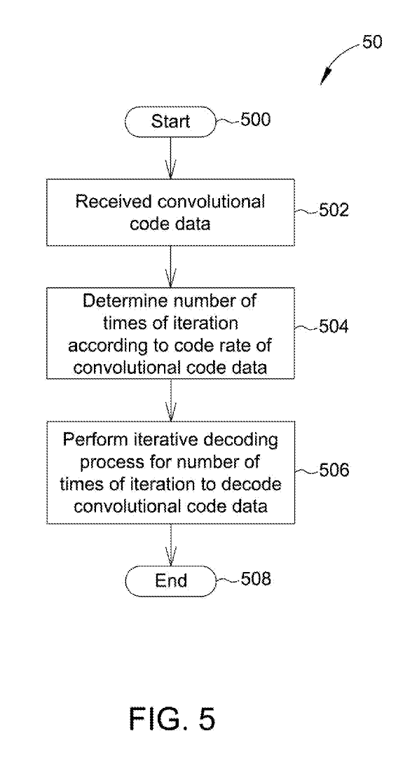

The process of the above decoding device 10 determining the number of times of iteration of an iterative decoding process according to the symbol rate SR of the convolutional code data received may be concluded into a decoding method 50. As shown in FIG. 5, the decoding method 50 may be applied to a convolutional code decoding device (e.g., the decoding device 10) in a communication system, and includes following steps.

In step 500, the decoding method 50 begins.

In step 502, convolutional code data is received.

In step 504, the number of times of iteration is determined according to a symbol rate of the convolutional code data.

In step 506, the iterative decoding process is performed for the number of times of iteration to decode the convolutional code data.

In step 508, the decoding method 50 ends.

According to the decoding method 50, the convolutional code decoding device first receives convolutional code data, and determines the number of times of iteration of the iterative decoding process for decoding the convolutional code data according to a symbol rate of the convolutional code data. In one embodiment, the convolutional code decoding device adjusts the length of a sliding window of the iterative decoding process according to the symbol rate of the convolutional code data to further determine the number of times of iteration of the iterative decoding process. The length of the sliding window is a unit length used for dividing the convolutional code data. Through the decoding method 50, the convolutional code decoding device may reduce the length of the sliding window when the symbol rate of the convolutional code data is increased to increase the number of times of iteration of the iterative decoding process to maintain the decoding accuracy of the convolutional code decoding device. On the other hand, when the symbol rate of the convolutional code data is reduced, the convolutional code decoding device increases the length of the sliding window to reduce the number of times of iteration of the iterative decoding process. With the reduced symbol rate of the convolutional code data, the decoding accuracy of the decoding device 10 still achieves the system requirements although the number of times of iteration of the convolutional code decoding process is reduced.

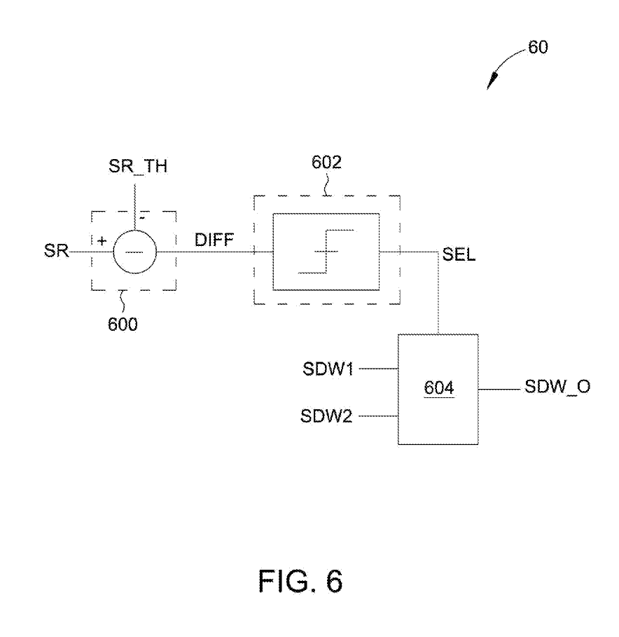

FIG. 6 shows a block diagram of a determination module 60 according to an embodiment of the present invention. The determination module 60 may be applied to a decoding circuit (e.g., the decoding device 10 in FIG. 1) with a MAP calculating function to adjust the window length (i.e., adjusting the number of times of iteration of an iterative decoding process) that the decoding circuit uses for performing an iterative decoding process according to a symbol rate of convolutional code data that the circuit receives. As shown in FIG. 6, the determination module 60 includes an arithmetic circuit 600, a determination circuit 602 and a selection circuit 604. The arithmetic circuit 600 may be a subtractor that calculates a difference between a symbol rate SR of the convolutional code data and a symbol rate threshold SR_TH as a difference signal DIFF. According to a relationship between the difference signal DIFF and 0, the determination circuit 602 generates a selection signal SEL to control the selection circuit 602 to output a window length SDW1 or SDW2 as a sliding window length SDW_O that the decoding circuit uses for performing the iterative decoding process. When the difference signal DIFF is smaller than 0 (the symbol rate SR is smaller than the symbol rate threshold SR_TH), the determination circuit 602 controls the selection circuit 604 to output the window length SDW1 as the sliding window length SDW_O that the decoding circuit uses for performing the iterative decoding process. When the difference signal DIFF is greater than 0 (the symbol rate SR is greater than the symbol rate threshold SR_TH), the determination circuit 602 controls the selection circuit 604 to output the window length SDW2 as the sliding window length SDW_O that the decoding circuit uses for performing the iterative decoding process. Thus, the determination module 60 may dynamically adjust the sliding window length that the decoding circuit uses for performing the iterative decoding process according to the symbol rate SR of the convolutional code data to enhance circuit performance.

In the above embodiments, the decoding device adjusts the number of times of iteration according to the symbol rate of the convolutional code data received, thereby simultaneously achieving real-time decoding and enhanced performance.

While the invention has been described by way of example and in terms of the preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A decoding method applied to a convolutional code decoding device in a communication system, comprising:
receiving convolutional code data;
determining the number of times of iteration according to a symbol rate of the convolutional code data; and
performing an iterative decoding process for the number of times of iteration to decode the convolutional code data.

2. The decoding method according to claim 1, wherein the number of times of iteration is directly proportional to the symbol rate.

3. The decoding method according to claim 1, wherein the step of determining the number of times of iteration according to the symbol rate of the convolutional code data comprises:
adjusting a length of a sliding window according to the symbol rate to determine the number of times of iteration;
wherein, the length of the sliding window is a unit length for dividing the convolutional code data in the iterative decoding process.

4. The decoding method according to claim 3, wherein the length of the sliding window is inversely proportional to the symbol rate.

5. The decoding method according to claim 3, wherein the step of adjusting the length of the sliding window according to the symbol rate to determine the number of times of iteration comprises:
when the symbol rate is smaller than a symbol rate threshold, adjusting the length of the sliding window to a first length; and
when the symbol rate is greater than the symbol rate threshold, adjusting the length of the sliding window to a second length;
wherein, the first length is greater than the second length.

6. The decoding method according to claim 1, wherein an equation for determining the number of times of iteration is:
$$floor ( \frac{( \frac{clockcycle \times FEC}{SR} ) - tre\_len - DS \times \frac{C 1 \times turbo\_clk}{FEC}}{\frac{tre\_len}{siso\_num} + SDW + SDW + C 2} ) ,$$
wherein, floor(x) is a function that obtains a maximum integer smaller than or equal to x, clockcycle is a clock cycle of the communication system, FEC is the number of the decoding device in the communication system, SR is the symbol rate of the convolutional code data, tre_len is the length of the convolutional code data, DS is the number of unit data size in the convolutional code data, turbo_clk is a clock cycle of the decoding device, siso_num is the number of hardware in the decoding device that processes the convolutional code data in parallel, SDW is a length of a sliding window for dividing the convolutional code data in the iterative decoding process, and C1 and C2 are parameters determined according to hardware characteristics of the communications system.

7. A determination module, applied to a convolutional code decoding device in a communication system, the determination module comprising:
an arithmetic circuit, calculating a difference between a symbol rate of convolutional code data that the convolutional code decoding device receives and a symbol rate threshold as a difference signal;
a determination circuit, generating a selection signal according to the difference signal; and
a selection circuit, outputting one of a first length and a second length according to the selection signal as a sliding window length of an iterative decoding process performed by the convolutional code decoding device.

8. The determination module according to claim 7, wherein when the difference signal indicates that the symbol rate is smaller than the symbol rate threshold, the determination circuit adjusts the selection signal to cause the selection signal to output the first length; when the difference signal indicates that the symbol rate is greater than the symbol rate threshold, the determination circuit adjusts the selection signal to cause the selection circuit to output the second length; the first length is greater than the second length.
